(19) United States
(12) Patent Application Publication
(10) Pub. No.: US 2026/0293529 A1
(43) Pub. Date: Sep. 24, 2026

(54) CERAMIC SPEAKER

(71) Applicant: AMOSENSE CO.,LTD, Cheonan-si, Chungcheongnam-do (KR)

(72) Inventors: Jae-Yong SONG, Cheonan-si, Chungcheongnam-do (KR); Jong-Kwan CHOI, Cheonan-si, Chungcheongnam-do (KR); Jeong-Sang YU, Cheonan-si, Chungcheongnam-do (KR); Chang-Woo OH, Cheonan-si, Chungcheongnam-do (KR)

(73) Assignee: AMOSENSE CO.,LTD, Cheonan-si, Chungcheongnam-do (KR)

(21) Appl. No.: 19/474,084

(22) PCT Filed: Apr. 9, 2024
(86) PCT No.: PCT/KR2024/004732

§ 371 Date: Oct. 9, 2025

(30) Foreign Application Priority Data
Apr. 10, 2023 (KR) 10-2023-0046819

(51) Int. Cl. H10N 30/87; H04R 17/00; H04R 31/00; H10N 30/053; H10N 30/097; H10N 30/20; H10N 30/853

(52) U.S. Cl. CPC H10N 30/871; H04R 17/00; H04R 31/00; H10N 30/053; H10N 30/097; H10N 30/20; H10N 30/8554; H10N 30/877

(57) ABSTRACT

Provided is a ceramic speaker composition that includes a ceramic, a sintering aid, and an oxide-based additive containing Bi₂O₃. The composition can be formed into a thin film, can be co-sintered with internal electrodes, and has excellent piezoelectric properties, and thus has the effects of exhibiting excellent performance and a high permittivity when applied to speakers.

### CROSS-REFERENCE TO RELATED APPLICATIONS

This application is the National Phase Entry of International Application No. PCT/KR2024/004732, filed on Apr. 9, 2024, which is based upon and claims priority to Korean Patent Application No. 10-2023-0046819, filed on Apr. 10, 2023, the entire contents of which are incorporated herein by reference.

### TECHNICAL FIELD

The present invention relates to a ceramic speaker, and more particularly, to a ceramic speaker including a multilayer sheet.

### BACKGROUND

In general, a piezoelectric element refers to a device having the characteristic of converting electrical energy and mechanical energy into each other. A piezoelectric speaker is a representative acoustic component that acoustically converts the mechanical motion of such a piezoelectric element into sound through a vibration plate, thereby generating sound in a desired audible frequency range.

A general piezoelectric speaker includes a piezoelectric element and a vibration plate, which is formed larger than the piezoelectric element and bonded to one surface of the piezoelectric element to amplify vibrations generated from the piezoelectric element. The acoustic characteristics of such a piezoelectric speaker are determined by the sound pressure at each frequency, and the sound pressure at each frequency may vary depending on the material and physical properties of the vibration plate.

Vibration plates applied to piezoelectric speakers are made of materials such as metal, polymer, or pulp.

In the case of a metal-based vibration plate, the metal has excellent elasticity and a high propagation speed, providing an advantage of converting the vibration of the piezoelectric element into sound waves with high output. However, vibration in the low-frequency range may not be sufficiently transmitted, resulting in sound pressure reduction in the low range, and only the middle- and high-frequency ranges are effectively reproduced. In addition, the metal vibration plate has disadvantages of increased thickness and heavy weight.

In the case of conventional coil motor-type speakers, the first resonance frequency (fₒ) is high, and the output sound pressure is also high. However, such speakers have difficulties in being made compact and lightweight compared with piezoelectric speakers, consume a large amount of power due to the current-driven mechanism, and generate heat during long-term use. In particular, they are disadvantageous in price competitiveness due to the rising cost of rare-earth raw materials.

In contrast, a piezoelectric speaker can be easily implemented as an ultrathin structure of 3 mm or less, consumes less power due to its voltage-driven operation, and is advantageous in weight reduction compared with conventional coil-type speakers. However, it has relatively low output sound pressure and poor low-frequency sound characteristics compared with coil-type speakers. However, in the case of a piezoelectric speaker, since the first resonance frequency (fₒ) is relatively higher than that of a general speaker, the sound pressure characteristics in the low-frequency range are weak, resulting in coarse and unpleasant sound.

Accordingly, there is an urgent need for the development of a piezoelectric speaker capable of exhibiting high sound pressure characteristics.

### SUMMARY OF THE INVENTION

The present invention has been devised to solve the above-described conventional problems, and an object of the present invention is to provide a ceramic speaker that can be made into a thin film, can exhibit excellent sound pressure characteristics at each frequency, and can be co-sintered with an internal electrode during manufacturing.

Another object of the present invention is to provide a ceramic speaker having excellent piezoelectric properties, thereby exhibiting superior performance when applied to a speaker and having high permittivity.

To solve the above-described problems, the present invention provides a ceramic speaker comprising: a ceramic sheet comprising two or more layers of sheets; and an electrode layer comprising metal layers disposed on an uppermost surface and a lowermost surface of the ceramic sheet and at interfaces between the respective sheets.

According to one embodiment of the present invention, the ceramic sheet may include an odd number of sheet layers.

In addition, the ceramic sheet may include three sheet layers.

In addition, each of the metal layers disposed at the interfaces between the respective sheets may have a smaller average thickness than each of the metal layers disposed on the uppermost surface and the lowermost surface.

Meanwhile, the sheets may be formed from a composition for a ceramic speaker including ceramics, a sintering aid, and an oxide-based additive comprising Bi₂O₃.

In addition, the ceramics may include a composition represented by the following Chemical Formula 1:

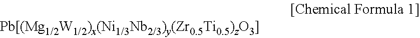

In addition, the oxide-based additive may be included in an amount of 0.3 to 1.3 parts by weight based on 100 parts by weight of the ceramics.

In addition, the sintering aid may include at least one selected from the group consisting of Li₂CO₃, CaCO₃, PbO, and CuO.

In addition, the sintering aid may be included in an amount of 0.2 to 1.5 parts by weight based on 100 parts by weight of the ceramics.

In addition, the ceramic speaker may have an average sound pressure level of 75 dB SPL or more in the range of 300 to 800 Hz.

The ceramic speaker of the present invention can be made into a thin film, can exhibit excellent sound pressure characteristics at each frequency, can be co-sintered with an internal electrode during manufacturing, and has excellent piezoelectric properties, thereby exhibiting superior performance when applied to a speaker and having high permittivity.

### BRIEF DESCRIPTION OF THE DRAWINGS

FIG. 1 is a schematic cross-sectional view illustrating a ceramic sheet and electrode layer of a ceramic speaker according to an exemplary embodiment of the present invention.

FIG. 2 is a schematic cross-sectional view illustrating a ceramic sheet and electrode layer of a ceramic speaker according to another exemplary embodiment of the present invention.

FIG. 3 is a schematic cross-sectional view illustrating a ceramic sheet and electrode layer of a ceramic speaker according to still another exemplary embodiment of the present invention.

### DETAILED DESCRIPTION

Hereinafter, exemplary embodiments of the present invention will be described in detail so that those of ordinary skill in the art can readily implement the present invention. The present invention may be embodied in many different forms and is not limited to the embodiments set forth herein.

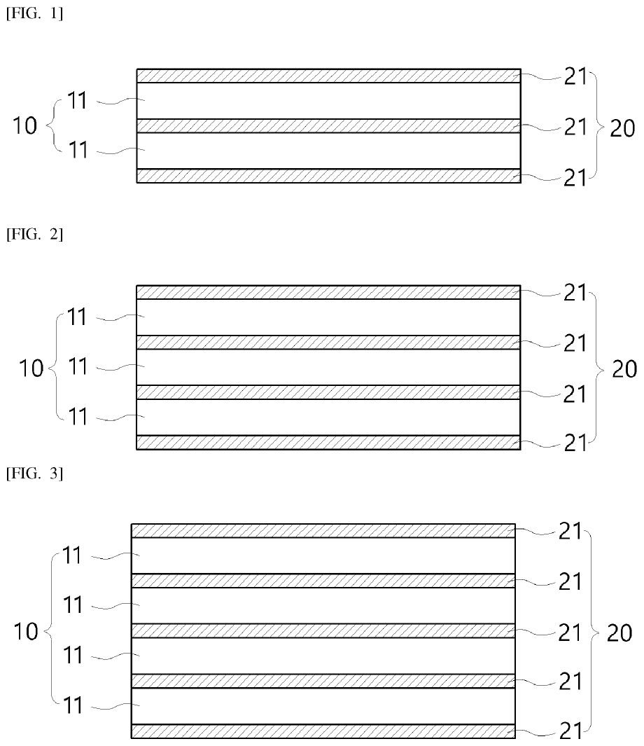

As shown in FIGS. 1 to 3, a ceramic speaker according to the present invention is implemented to include a ceramic sheet 10 including two or more layers of sheets 11, and an electrode layer 20 including metal layers 21 disposed on the uppermost surface and the lowermost surface of the ceramic sheet 10 and at the interfaces between the respective sheets 11.

Hereinafter, each component of the ceramic speaker according to the present invention will be described in detail.

First, the ceramic sheet 10, as described above, includes two or more layers of sheets 11, preferably may include an odd number of sheets 11, more preferably, may include three or five layers of sheets 11, and most preferably, may include three layers of sheets 11, which is advantageous for achieving the object of the present invention.

Meanwhile, each of the sheets 11 may independently have an average thickness of 20 to 70 μm, preferably 30 to 60 μm, more preferably 35 to 55 μm, and most preferably 40 to 50 μm. If the average thickness of each sheet is less than 20 μm, reliability may be degraded, and if it exceeds 70 μm, the performance of the speaker may deteriorate.

In this case, the respective sheets 11 may have the same or different average thicknesses, and the present invention is not particularly limited thereto.

In addition, the total average thickness of the sheets 11 may be 100 to 250 μm, preferably 105 to 200 μm, more preferably 105 to 180 μm, and most preferably 110 to 150 μm. If the total average thickness of the sheets is less than 100 μm or exceeds 250 μm, the sound pressure characteristics or reliability may be degraded.

Meanwhile, each of the sheets 11 may be formed from a composition for a ceramic speaker including ceramics, a sintering aid, and an oxide-based additive comprising Bi₂O₃.

The ceramics may include one of known lead-based piezoelectric ceramic components and lead-free piezoelectric ceramic components, a mixture thereof, or an alloy thereof. Preferably, the ceramics may include at least one selected from the group consisting of lead zirconate titanate (PZT), lead magnesium niobate (PMN), lead nickel niobate (PNN), lead titanate (PT), lead magnesium tungstate (PMW), PNN-PZT, PMN-PT, PMW-PZT, BS-PT, and lanthanum-doped lead zirconate titanate (PLZT). More preferably, the ceramics may include a mixture or an alloy of at least one selected from the group consisting of Pb(Ti, Zr)O₃, Pb(Mg_{1/3}Nb_{2/3})O₃, Pb(Mg_{1/3}Ta_{2/3})O₃, Pb(Ni_{1/3}Nb_{2/3})O₃, Pb(Mn_{1/3}Ta_{2/3})O₃, Pb(Mn_{1/3}Sb_{2/3})O₃, Pb(Zn_{1/3}Nb_{2/3})O₃, Pb(Zn_{1/3}Ta_{2/3})O₃, Pb(Mn_{1/3}Nb_{2/3})O₃, Pb(Co_{1/3}Sb_{2/3})O₃, Pb(Zn_{1/3}Nb_{2/3})O₃, Pb(Co_{1/3}Nb_{2/3})O₃, Pb(Fe_{1/3}Sb_{2/3})O₃, Pb(Fe_{1/3}Nb_{2/3})O₃, Pb(Mn_{1/3}Bi_{2/3})O₃, Pb(Mg_{1/3}Nb_{2/3})O₃, Pb(Mg_{1/3}Ta_{2/3})O₃, Pb(Ni_{1/3}Nb_{2/3})O₃, Pb(Mn_{1/3}Ta_{2/3})O₃, Pb(Mn_{1/3}Sb_{2/3})O₃, Pb(Zn_{1/3}Nb_{2/3})O₃, Pb(Zn_{1/3}Ta_{2/3})O₃, Pb(Mn_{1/3}Nb_{2/3})O₃, Pb(Co_{1/3}Sb_{2/3})O₃, Pb(Zn_{1/3}Nb_{2/3})O₃, Pb(Co_{1/3}Nb_{2/3})O₃, Pb(Fe_{1/3}Sb_{2/3})O₃, Pb(Fe_{1/3}Nb_{2/3})O₃, Pb(Mn_{1/3}Bi_{2/3})O₃, Pb(Cd_{1/2}W_{1/2})O₃, Pb(Mg_{1/2}W_{1/2})O₃, Pb(Co_{1/2}W_{1/2})O₃, Pb(Ni_{1/2}W_{1/2})O₃, Pb(Mn_{1/2}W_{1/2})O₃, Pb(Ca_{1/2}W_{1/2})O₃, Pb(Fe_{2/3}W_{1/3})O₃, Pb(Mn_{2/3}W_{1/3})O₃, La(Mg_{1/2}Ti_{1/2})O₃, Nd (Mg_{1/2}Ti_{1/2})O₃, Pb(Li_{1/4}Nb_{3/4})O₃, Pb(Cu_{1/4}Nb_{3/4})O₃, Pb(Li_{1/4}Sb_{3/4})O₃, and Pb(Mg_{1/2}W_{1/2})O₃—Pb(Ni_{1/3}Nb_{2/3})O₃—(Zr_{0.5}Ti_{0.5})O₃. Still more preferably, the ceramics may include a composition represented by Pb[(Mg_{1/2}W_{1/2})ₓ(Ni_{1/3}Nb_{2/3})_{y}(Zr_{0.5}Ti_{0.5})_{z}O₃], where x, y, and z are each independently a rational number from 0.01 to 0.99, and x+y+z=1, and most preferably, may include a composition represented by Pb[(Mg_{1/2}W_{1/2})_{0.03}(Ni_{1/3}Nb_{2/3})_{0.09}(Zr_{0.5}Ti_{0.5})_{0.88}O₃], which is more advantageous for achieving the object of the present invention.

In addition, the sintering aid serves to assist the sintering of the ceramics, and any sintering aid that can be conventionally used in the art may be employed without limitation. Preferably, the sintering aid may include at least one selected from the group consisting of Li₂CO₃, CaCO₃, PbO, and CuO, and more preferably, may include one or more of Li₂CO₃ and CaCO₃, which is more advantageous for achieving the object of the present invention.

In this case, the sintering aid may be included in an amount of 0.2 to 1.5 parts by weight based on 100 parts by weight of the ceramics, and preferably in an amount of 0.3 to 1.0 parts by weight. If the amount of the sintering aid is less than 0.2 parts by weight or exceeds 1.5 parts by weight based on 100 parts by weight of the ceramics, the piezoelectric property may be deteriorated.

In addition, the oxide-based additive can lower the sintering temperature of the ceramics, thereby enabling co-sintering with an internal electrode, and serves to provide excellent piezoelectric properties so that superior performance can be achieved when applied to a speaker.

The oxide-based additive may include Bi₂O₃ as described above and may further include Sb₂O₅. However, it is preferable that the oxide-based additive includes only Bi₂O₃, which can lower the sintering temperature of the ceramics, thereby enabling co-sintering with an internal electrode, and is more advantageous in that excellent piezoelectric properties can be achieved, resulting in superior performance when applied to a speaker. Meanwhile, when Sb₂O₅ is further included, the sinterability may be relatively degraded compared to when it is not included, thereby lowering the piezoelectric property and permittivity. Therefore, the oxide-based additive may not include Sb₂O₅.

In this case, the oxide-based additive may be included in an amount of 0.3 to 1.3 parts by weight based on 100 parts by weight of the ceramics, and preferably in an amount of 0.5 to 1 parts by weight. If the oxide-based additive is less than 0.3 parts by weight based on 100 parts by weight of the ceramics, the sinterability may be poor, and the piezoelectric property and permittivity may be low. On the other hand, if the oxide-based additive exceeds 1.3 parts by weight based on 100 parts by weight of the ceramics, the piezoelectric property may be reduced.

Meanwhile, the composition for a ceramic speaker may further include a solvent.

The solvent may be a known solvent that facilitates the dispersion of the above-described ceramics, sintering aid, and oxide-based additive, and does not interfere with the dissolution of a binder when the composition includes a binder. For example, the solvent may be a mixed solvent including one or more organic solvents such as toluene and ethanol.

In addition, the composition for a ceramic speaker may further include, in addition to the components described above, known binders, plasticizers, dispersants, or defoaming agents, and the present invention is not particularly limited thereto.

Non-limiting examples of the plasticizer may include phthalate esters such as dioctyl-4,5-epoxy-hexahydrophthalate, tris-(octoxycarbonylethyl) isocyanurate, tristearin, epoxidized soybean oil, and other similar compounds, or mixtures thereof.

Next, the electrode layer 20 includes a metal layer 21 as described above.

The metal layers 21 are disposed on the uppermost surface and the lowermost surface of the ceramic sheet 10 and at the interfaces between the respective sheets 11.

The material of the metal layer 21 may be any material that can be conventionally used for metal layers in the art without limitation, but preferably includes silver (Ag), which is more advantageous for achieving the object of the present invention.

Meanwhile, among the metal layers 21, the metal layers (internal electrodes) disposed at the interfaces between the respective sheets 11 may each independently have an average thickness of 1 to 10 μm, preferably 2 to 7 μm, and more preferably 2.5 to 5 μm. If the average thickness of the metal layer (internal electrode) deviates from the above range, the electrode connectivity may be degraded.

In addition, among the metal layers 21, the metal layers (external electrodes) disposed on the uppermost and lowermost surfaces may each independently have an average thickness of 2 to 20 μm, preferably 3 to 10 μm, and more preferably 4 to 7 μm. If the average thickness of the metal layer (external electrode) is less than 2 μm, solderability may be degraded, and if it exceeds 20 μm, the sound pressure characteristics may deteriorate.

In this case, the respective metal layers 21 may have the same or different average thicknesses, and the present invention is not particularly limited thereto.

In addition, the ceramic speaker according to the present invention may have an average sound pressure level of 75 dB SPL or more in the range of 300 to 800 Hz, preferably 77 dB SPL or more in the range of 300 to 800 Hz, more preferably 80 dB SPL or more in the range of 300 to 800 Hz, and still more preferably 82 dB SPL or more in the range of 300 to 800 Hz.

In addition, the ceramic speaker according to the present invention may have an average sound pressure level of 70 dB SPL or more in the range of 150 to 2,000 Hz, preferably 73 dB SPL or more in the range of 150 to 2,000 Hz, and more preferably 77 dB SPL or more in the range of 150 to 2,000 Hz.

In addition, the ceramic speaker according to the present invention may have an average sound pressure level of 72 dB SPL or more in the range of 150 to 1,000 Hz, preferably 75 dB SPL or more in the range of 150 to 1,000 Hz, and more preferably 79 dB SPL or more in the range of 150 to 1,000 Hz.

In addition, the ceramic speaker according to the present invention may have an average sound pressure level of 69 dB SPL or more in the range of 1,000 to 10,000 Hz, preferably 72 dB SPL or more in the range of 1,000 to 10,000 Hz, and more preferably 76 dB SPL or more in the range of 1,000 to 10,000 Hz.

In addition, the ceramic speaker according to the present invention may have an average sound pressure level of 68 dB SPL or more in the range of 2,000 to 4,000 Hz, preferably 71 dB SPL or more in the range of 2,000 to 4,000 Hz, and more preferably 75 dB SPL or more in the range of 2,000 to 4,000 Hz.

In addition, the ceramic speaker according to the present invention may have an average sound pressure level of 71 dB SPL or more in the range of 150 to 8,000 Hz, preferably 74 dB SPL or more in the range of 150 to 8,000 Hz, and more preferably 78 db SPL or more in the range of 150 to 8,000 Hz.

Since the ceramic speaker according to the present invention satisfies the above ranges of average sound pressure levels for each frequency, it can exhibit the effect of being capable of forming a thin film while providing excellent sound pressure characteristics at each frequency.

Meanwhile, the ceramic speaker according to the present invention may be manufactured by a manufacturing method to be described later, but is not limited thereto.

The ceramic speaker according to the present invention may be manufactured by including a step of sintering the above-described composition for a ceramic speaker.

The sintering step may be performed at a temperature of 880 to 960° C., preferably at a temperature of 900 to 940° C., and more preferably at a temperature of 910 to 930° C. If the sintering temperature is lower than 880° C., sintering may not proceed to a desired level, resulting in low piezoelectric property and permittivity.

If the sintering temperature exceeds 960° C., the connectivity of the Ag internal electrode may deteriorate, thereby lowering the permittivity and sound pressure characteristics.

In addition, the sintering step may be performed for 1 to 3 hours, preferably for 1.5 to 2.5 hours. If the sintering step is performed for less than 1 hour, sintering may not proceed to a desired level, resulting in low piezoelectric property and permittivity. If the sintering step is performed for more than 3 hours, reliability degradation and an increase in permittivity may occur.

In this case, the sintering step may be performed such that the composition for a ceramic speaker and the metal forming the above-described metal layer are co-sintered, whereby the process can be simplified while simultaneously exhibiting excellent piezoelectric property and permittivity.

Meanwhile, the above-described composition for a ceramic speaker may further include a binder, and the method for manufacturing a ceramic speaker according to the present invention may further include a step of removing the binder before the sintering step.

The binder removal step may be performed under conditions that can be conventionally used in the art, and preferably at a temperature of 240 to 300° C., and more preferably at a temperature of 260 to 280° C.

Meanwhile, the method for manufacturing a ceramic speaker according to the present invention may further include, before the step of removing the binder, forming the above-described composition for a ceramic speaker into sheets; laminating two or more layers of the sheet-shaped compositions for a ceramic speaker; and disposing a metal for forming a metal layer on the uppermost surface and the lowermost surface of the laminated sheet-shaped composition for a ceramic speaker and at the interfaces between the respective sheet-shaped compositions for a ceramic speaker.

In this case, the step of forming into a sheet may be performed without limitation by any sheet-forming method conventionally used in the art, and preferably by a casting or pressing method, but is not limited thereto.

In addition, the laminating step may be performed by any method conventionally used in the art, and therefore, the present invention is not particularly limited thereto.

### MODE FOR CARRYING OUT THE INVENTION

The present invention will be described in more detail through the following ng examples, but the following examples are not intended to limit the scop e of the present invention, which should be construed to aid understanding of the present invention.

### EXAMPLES

### Example 1

First, a composition for a ceramic speaker was prepared by including 0.6 parts by weight of an oxide-based additive of Bi₂O₃, 0.7 parts by weight of a sintering aid containing Li₂CO₃ and CaCO₃ in a weight ratio of 1:1, and 6.5 parts by weight of a binder, based on 100 parts by weight of ceramics having an average particle size of 0.75 μm and a composition represented by

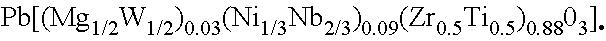

The prepared composition for a ceramic speaker was molded into sheets by a tape casting method, and three sheet-shaped compositions for a ceramic speaker were laminated to form a laminate. A metal for forming a metal layer, namely silver (Ag), was disposed on the uppermost surface and the lowermost surface of the laminate and on the interfaces between the respective sheet-shaped compositions for a ceramic speaker. The laminate was then heated in a furnace at a heating rate of 0.2° C./min to 270° C. and heat-treated for 3 hours to remove the binder, followed by heating at a heating rate of 3° C./min and maintaining the temperature at 920° C. for 2 hours to perform sintering. Afterward, the laminate was cooled under natural cooling conditions to produce a ceramic speaker module as shown in FIG. 2, including a ceramic sheet having three layers of sheets and an electrode layer including metal layers disposed on the uppermost and lowermost surfaces of the ceramic sheet and at the interfaces between the three sheets. In this case, each of the three layers of sheets had an average thickness of 43 μm, the metal layers on the uppermost and lowermost surfaces of the ceramic sheet had a thickness of 10 μm, and the metal layers disposed at the interfaces between the three layers of sheets had a thickness of 5 μm.

### Examples 2 to 3 and Comparative Example 1

Ceramic speaker modules were manufactured in the same manner as in Example 1, except that the number and thickness of the laminated sheets and the number of metal layers disposed at the interfaces between the sheets were changed.

### Experimental Example 1: Measurement of Average Sound Pressure Level by Frequency

For each of the ceramic speaker modules manufactured according to the Examples and Comparative Example, each ceramic speaker module was placed on a SUS plate having a width of 30 cm and a length of 30 cm, and a voltage of 7 V was applied to a microphone positioned at a distance of 0.5 m to measure the average sound pressure level at the respective frequencies shown below. The results are shown in Table 1.
Frequency range: 150-2,000 Hz
Frequency range: 150-1,000 Hz
Frequency range: 300-800 Hz
Frequency range: 1,000-10,000 Hz
Frequency range: 2,000-4,000 Hz
Frequency range: 150-8,000 Hz

TABLE 1

| | | | Example | Example | Example | Comparative |
|---|---|---|---|---|---|---|
| Classification | | | 1 | 2 | 3 | Example 1 |
| Ceramic sheet | Number of sheet layers | | 3 layers | 2 layers | 4 layers | 1 layer |
| Metal layer | Thickness of metal layer (μm) | | 10 | 10 | 10 | 10 |
| 1st-layer sheet | Sheet thickness (μm) | | 43 | 67 | 45 | 150 |
| Metal layer | Thickness of metal layer (μm) | | 5 | 5 | 5 | 10 |
| 2nd-layer sheet | Sheet thickness (μm) | | 43 | 67 | 45 | — |
| Metal layer | Thickness of metal layer (μm) | | 5 | 10 | 5 | — |
| 3rd-layer sheet | Sheet thickness (μm) | | 43 | — | 45 | — |
| Metal layer | Thickness of metal layer (μm) | | 10 | — | 5 | — |
| 4th-layer sheet | Sheet thickness (μm) | | — | — | 45 | — |
| Metal layer | Thickness of metal layer (μm) | | — | — | 10 | — |
| Total thickness of ceramic sheet | | | 159 | 159 | 215 | 170 |
| and electrode layer (μm) | | | | | | |
| Average sound | 150-2,000 | Hz | 78.81 | 69.98 | 79.58 | 69.07 |
| pressure level by | 150-1,000 | Hz | 80.78 | 71.25 | 81.39 | 69.27 |
| frequency (dB SPL) | 300-800 | Hz | 83.28 | 73.68 | 83.83 | 71.65 |
| | 1,000-10,000 | Hz | 77.73 | 67.89 | 78.30 | 68.07 |
| | 2,000-4,000 | Hz | 76.37 | 66.53 | 78.18 | 68.08 |
| | 150-8,000 | Hz | 79.18 | 69.39 | 79.67 | 68.49 |

As shown in Table 1, Examples 1 to 3, which satisfy all the conditions including the number of laminated sheets according to the present invention, exhibit significantly superior average sound pressure levels by frequency compared with Comparative Example 1, which does not satisfy such conditions. Specifically, Example 1, in which three sheets were laminated, showed a remarkably higher average sound pressure level by frequency than Example 2, in which two sheets were laminated.

In addition, Example 1, in which three sheets were laminated, exhibited sound pressure characteristics equivalent to those of Example 3, in which four sheets were laminated, while having a thinner thickness.

Furthermore, Example 1, in which three sheets were laminated, showed a remarkably higher average sound pressure level by frequency than Comparative Example 1, in which a single sheet was laminated.

### Examples 4 to 11

Ceramic speaker modules as shown in Tables 2 and 3 were manufactured in the same manner as in Example 1, except that the material type and content of the oxide-based additive were changed.

### Experimental Example 2

For each of the ceramic speaker modules manufactured according to Example 1 and Examples 4 to 11, the following physical properties were evaluated, and the results are shown in Tables 2 and 3.

### 1. Measurement of Permittivity

For each of the sintered ceramics manufactured according to Example 1 and Examples 4 to 11, the capacitance of the product was measured using a capacitance meter, and the permittivity was calculated based on the measured values.

### 2. Measurement of Piezoelectric Constant d₃₃

For each of the sintered ceramics manufactured according to Example 1 and Examples 4 to 11, the piezoelectric constant d₃₃ was measured using a d₃₃ meter.

TABLE 2

| | | Example | Example | Example | Example | Example |
|---|---|---|---|---|---|---|
| Classification | | 1 | 4 | 5 | 6 | 7 |
| Oxide-based | Material type | Bi₂O₃ | Bi₂O₃ | Bi₂O₃ | Bi₂O₃ | Bi₂O₃ |
| additive | Content (parts by weight) | 0.6 | 0.5 | 0.8 | 1 | 1.5 |

| | | | | | |
|---|---|---|---|---|---|
| Permittivity (F/m) | 2523 | 2472 | 2604 | 2640 | 2292 |
| Piezoelectric constant d₃₃ (pC/N) | 649 | 655 | 647 | 620 | 588 |

TABLE 3

| Classification | | Example 8 | Example 9 | Example 10 | Example 11 |
|---|---|---|---|---|---|
| Oxide-based | Material type | Bi₂O₃/Sb₂O₅ | Bi₂O₃/Sb₂O₅ | Bi₂O₃ | Sb₂O₅ |
| additive | Content (parts by weight) | 0.6/0.2 | 0.6/0.3 | 0 | 0.6 |

| | | | | |
|---|---|---|---|---|
| Permittivity (F/m) | 2030 | 1248 | 995 | 462 |
| Piezoelectric constant d₃₃ (pC/N) | 595 | 417 | 282 | 79 |

As shown in Tables 1 to 3, Example 1 and Examples 4 to 6, which satisfy all the conditions regarding the material type and content of the oxide-based additive according to the present invention, were found to simultaneously exhibit significantly superior permittivity and piezoelectric properties (piezoelectric constant d₃₃) compared with Examples 7 to 11, which fail to satisfy at least one of these conditions. Specifically, it can be confirmed that Example 1 and Examples 4 to 6, which satisfy the content range of Bi₂O₃ according to the present invention, exhibit significantly superior permittivity and piezoelectric properties compared with Example 7, in which the content of Bi₂O₃ exceeds the defined range.

In addition, it can be confirmed that Example 1, in which the oxide-based additive according to the present invention does not include Sb₂O₅, exhibits significantly superior permittivity and piezoelectric properties compared with Examples 8 and 9, in which the oxide-based additive includes Sb₂O₅. In particular, it was observed that as the content of Sb₂O₅ increases, the permittivity and piezoelectric properties gradually decrease.

It can also be confirmed that Example 1 and Examples 4 to 6, which satisfy the content range of Bi₂O₃ according to the present invention, exhibit significantly superior permittivity and piezoelectric properties compared with Example 10, in which the content of Bi₂O₃ is below the defined range.

Furthermore, it can be confirmed that Example 1, in which the oxide-based additive according to the present invention includes Bi₂O₃, exhibits significantly superior permittivity and piezoelectric properties compared with Example 11, in which the oxide-based additive does not include Bi₂O₃.

Although exemplary embodiments of the present invention have been described above, the scope of the present invention is not limited to the embodiments set forth herein. Those skilled in the art who understand the spirit of the present invention may readily propose other embodiments by adding, modifying, deleting, or supplementing components within the scope of the present invention, and such embodiments should also be regarded as falling within the scope of the present invention.

### DESCRIPTION OF SYMBOLS

10: ceramic sheet
11: sheet
20: electrode layer
21: metal layer

1. A ceramic speaker comprising:
a ceramic sheet comprising two or more layers of sheets; and
an electrode layer comprising metal layers disposed on an uppermost surface and a lowermost surface of the ceramic sheet and at interfaces between the respective sheets.

2. The ceramic speaker of claim 1, wherein the ceramic sheet includes an odd number of sheet layers.

3. The ceramic speaker of claim 1, wherein the ceramic sheet comprises three sheet layers.

4. The ceramic speaker of claim 1, wherein each of the metal layers disposed at the interfaces between the respective sheets has a smaller average thickness than each of the metal layers disposed on the uppermost surface and the lowermost surface.

5. The ceramic speaker of claim 1, wherein the sheets are formed from a composition for a ceramic speaker comprising:
ceramics;
a sintering aid; and
an oxide-based additive comprising Bi₂O₃.

6. The ceramic speaker of claim 5, wherein the ceramics comprise a composition represented by the following Chemical Formula 1: 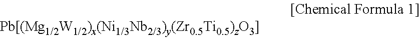
where x, y, and z are each independently a rational number from 0.01 to 0.99, and x+y+Z=1.

7. The ceramic speaker of claim 5, wherein the oxide-based additive is included in an amount of 0.3 to 1.3 parts by weight based on 100 parts by weight of the ceramics.

8. The ceramic speaker of claim 5, wherein the sintering aid comprises at least one selected from the group consisting of Li₂CO₃, CaCO₃, PbO, and CuO.

9. The ceramic speaker of claim 5, wherein the sintering aid is included in an amount of 0.2 to 1.5 parts by weight based on 100 parts by weight of the ceramics.

10. The ceramic speaker of claim 1, wherein the ceramic speaker has an average sound pressure level of 75 dB SPL or more in the range of 300 to 800 Hz.
